(19) United States
(12) Patent Application Publication
(10) Pub. No.: US 2025/0072073 A1
(43) Pub. Date: Feb. 27, 2025

(54) APPARATUS FOR ADJUSTING SPACING BETWEEN MOIRE SUPERLATTICES OF TWO-DIMENSIONAL MATERIALS

(71) Applicant: University-Industry Cooperation Group of Kyung Hee University, Yongin-si (KR)

(72) Inventors: Young Duck KIM, Seongnam-si (KR); Kwang Hee HAN, Busan (KR)

(73) Assignee: University-Industry Cooperation Group of Kyung Hee University, Yongin-si (KR)

(21) Appl. No.: 18/802,935

(22) Filed: Aug. 13, 2024

(30) Foreign Application Priority Data
Aug. 21, 2023 (KR) 10-2023-0108800

(51) Int. Cl. H01L 29/15

(52) U.S. Cl. CPC H01L 29/15

(57) ABSTRACT

Disclosed is an apparatus for adjusting spacing between Moiré superlattices of two-dimensional (2-D) materials. A heterostructure 2-D material includes a first insulator, a first 2-D material having one surface coming into contact with the first insulator, a second 2-D material having one surface coming into contact with the first 2-D material and forming a van der Waals layered bond, a second insulator having one surface coming into contact with the second 2-D material, and an electrode configured to come into contact with the other surface of the second insulator and rotated by electrostatic attraction from the outside.

### CROSS-REFERENCE TO RELATED APPLICATION

This application claims priority to Korean Patent Application No. 10-2023-0108800 filed on Aug. 21, 2023, the entire contents of which are herein incorporated by reference.

This patent is the results of research that was carried out by the support (a unique project number: 1711199107, a detailed project number: 2022M3H4A1A04096396, a project name: The Development of two-dimensional boron nitride-based quantum light source technology that operates at room temperature of the National Research Foundation of Korea by the finances of the government of the Republic of Korea (The Ministry of Science and ICT) in 2023.

### BACKGROUND

### 1. Technical Field

The present embodiment relates to an apparatus for adjusting spacing between Moiré superlattices of two-dimensional (2-D) materials that are bonded together.

### 2. Related Art

Contents described in this part merely provide background information of the present embodiment, and do not constitute a conventional technology.

A two-dimensional (2-D) material is a material in which atoms or compounds having several nanometers have been arranged as a layer. In particular, a heterostructure, that is, a structure in which materials composed of a 2-D thin film have been vertically stacked by the van der Waals Interaction has a specific characteristic. Research for applying such a 2-D material to solar cells or a display in addition to a semiconductor is continued because the 2-D material has thin, well-bent, and stiff characteristics.

Spacing between Moiré superlattices of 2-D materials implemented to have the heterostructure is determined depending on an angle at which the other material is disposed with respect to one material. As the spacing between the Moiré superlattices is changed, the 2-D materials having the heterostructure have different superconducting properties, electrical properties, semiconductor properties, or optical properties. Accordingly, an angle at which each of the 2-D materials has to be disposed is different depending on how the 2-D materials having the heterostructure will be used.

Conventionally, an angle between 2-D materials implemented to have a heterostructure is determined upon manufacturing, and is not subsequently adjusted. In particular, the angle between the 2-D materials is not precisely adjusted even in its manufacturing process, and can be checked even after the manufacturing of the 2-D materials. Accordingly, in manufacturing 2-D materials (implemented to have a heterostructure) having a desired angle therebetween, conventionally, there are problems in that it is inconvenient because a significantly long time and costs are consumed in the manufacturing of the 2-D materials and the yield of the 2-D materials is very low.

### SUMMARY

An embodiment of the present disclosure is directed to providing an apparatus capable of easily and precisely adjusting spacing between Moiré superlattices of 2-D materials that are bonded together even after the 2-D materials are manufacture.

According to an aspect of the present embodiment, a heterostructure two-dimensional (2-D) material includes a first insulator, a first 2-D material having one surface coming into contact with the first insulator, a second 2-D material having one surface coming into contact with the first 2-D material and forming a van der Waals layered bond, a second insulator having one surface coming into contact with the second 2-D material, and an electrode configured to come into contact with the other surface of the second insulator and rotated by electrostatic attraction from the outside.

According to an aspect of the present embodiment, the first insulator and the first 2-D material are fixed.

According to an aspect of the present embodiment, the second insulator, the second 2-D material, and the electrode are rotated.

According to an aspect of the present embodiment, the second insulator and the second 2-D material are rotated along with the rotation of the electrode.

According to an aspect of the present embodiment, the electrode is implemented in the form of sawteeth that are rotated around a central axis of the electrode.

According to an aspect of the present embodiment, the electrode is made of a metal material that is subjected to the electrostatic attraction.

According to an aspect of the present embodiment, an apparatus for adjusting spacing between Moiré superlattices of two-dimensional (2-D) materials includes the heterostructure 2-D material, a plurality of second electrodes disposed to be spaced apart from the electrode by a predetermined distance on an outer circumferential surface of the electrode and configured to generate the electrostatic attraction by a voltage, a power supply configured to apply the voltage to each of the plurality of second electrodes so that any one or a plurality of the second electrodes generates the electrostatic attraction, an electric wire configured to transfer the voltage supplied by the power supply to each of the plurality of second electrodes by electrically connecting the plurality of second electrodes and the power supply, and a plurality of switches each disposed in an electrical path of the power supply and each of the plurality of second electrodes and configured to adjust whether to supply each of the plurality of second electrodes with the voltage supplied by the power supply.

According to an aspect of the present embodiment, the sawteeth of the electrode include sawteeth that are implemented as many as a first multiple of a preset numerical value.

According to an aspect of the present embodiment, the plurality of second electrodes is disposed as many as a second multiple of the preset numerical value.

According to an aspect of the present embodiment, the plurality of second electrodes is disposed at equal intervals.

According to an aspect of the present embodiment, an apparatus for adjusting spacing between Moiré superlattices of two-dimensional (2-D) materials includes the heterostructure 2-D material, a plurality of second electrodes disposed to be spaced apart from the electrode by a predetermined distance on an outer circumferential surface of the electrode and configured to generate the electrostatic attraction by a voltage, a power supply configured to apply the voltage to each of the plurality of second electrodes so that any one or a plurality of the second electrodes generates the electrostatic attraction and to apply the voltage to a preset number of second electrodes simultaneously, and an electric wire configured to transfer the voltage supplied by the power supply to each of the plurality of second electrodes by electrically connecting each of the plurality of second electrodes and the power supply.

According to an aspect of the present embodiment, the plurality of second electrodes is disposed as many as a second multiple of the preset numerical value.

According to an aspect of the present embodiment, the power supply applies the voltage to the plurality of second electrodes disposed to have equal intervals, in applying the voltage to the preset number of second electrodes simultaneously.

As described above, according to an aspect of the present embodiment, there is an advantage in that spacing between Moiré superlattices of 2-D materials that are bonded together can be easily and precisely adjusted even after the 2-D materials are manufactured.

### BRIEF DESCRIPTION OF THE DRAWINGS

FIG. 1 is a perspective view of an apparatus for adjusting spacing between Moiré superlattices of 2-D materials according to an embodiment of the present disclosure.

FIGS. 2A and 2B are plan views of the apparatus for adjusting spacing between Moiré superlattices of 2-D materials according to an embodiment of the present disclosure.

FIG. 3 is a cross-sectional view of a heterostructure 2-D material according to an embodiment of the present disclosure.

FIG. 4 is a plan view of the heterostructure 2-D material according to an embodiment of the present disclosure.

FIGS. 5A and 5B are diagrams illustrating Moiré patterns that are formed based on the angles of the heterostructure 2-D material.

FIGS. 6A, 6B, and 6C are diagrams illustrating an operation of the apparatus for adjusting spacing between Moiré superlattices of 2-D materials according to an embodiment of the present disclosure.

### DETAILED DESCRIPTION

The present disclosure may be changed in various ways and may have various embodiments. Specific embodiments are to be illustrated in the drawings and specifically described. It should be understood that the present disclosure is not intended to be limited to the specific embodiments, but includes all of changes, equivalents and/or substitutions included in the spirit and technical range of the present disclosure. Similar reference numerals are used for similar components while each drawing is described.

Terms, such as a first, a second, A, and B, may be used to describe various components, but the components should not be restricted by the terms. The terms are used to only distinguish one component from another component. For example, a first component may be referred to as a second component without departing from the scope of rights of the present disclosure. Likewise, a second component may be referred to as a first component. The term “and/or” includes a combination of a plurality of related and described items or any one of a plurality of related and described items.

When it is described that one component is “connected” or “coupled” to the other component, it should be understood that one component may be directly connected or coupled to the other component, but a third component may exist between the two components. In contrast, when it is described that one component is “directly connected to” or “directly coupled to” the other component, it should be understood that a third component does not exist between the two components.

Terms used in this application are used to only describe specific embodiments and are not intended to restrict the present disclosure. An expression of the singular number includes an expression of the plural number unless clearly defined otherwise in the context. In this specification, a term, such as “include” or “have”, is intended to designate the presence of a characteristic, a number, a step, an operation, a component, a part or a combination of them, and should be understood that it does not exclude the existence or possible addition of one or more other characteristics, numbers, steps, operations, components, parts, or combinations of them in advance.

All terms used herein, including technical terms or scientific terms, have the same meanings as those commonly understood by a person having ordinary knowledge in the art to which the present disclosure pertains, unless defined otherwise in the specification.

Terms, such as those defined in commonly used dictionaries, should be construed as having the same meanings as those in the context of a related technology, and are not construed as ideal or excessively formal meanings unless explicitly defined otherwise in the application.

Furthermore, each construction, process, procedure, or method included in each embodiment of the present disclosure may be shared within a range in which the constructions, processes, procedures, or methods do not contradict each other technically.

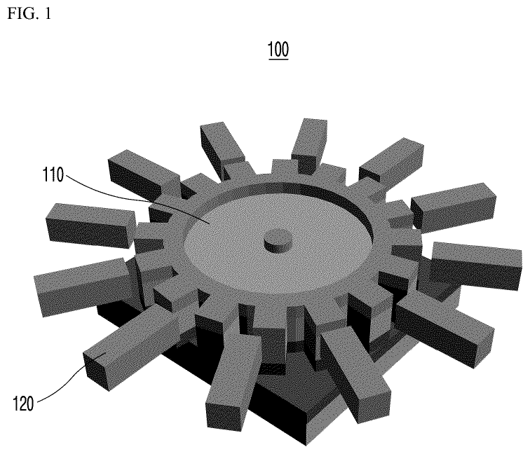

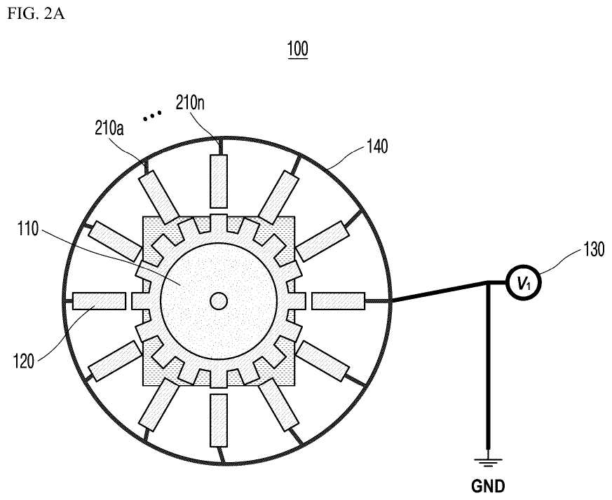

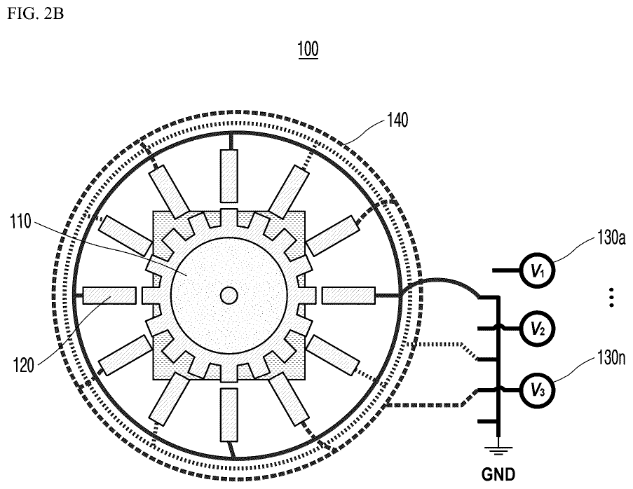

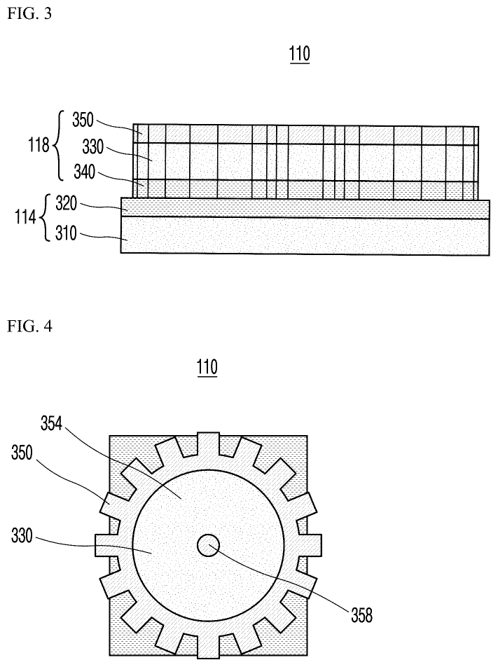

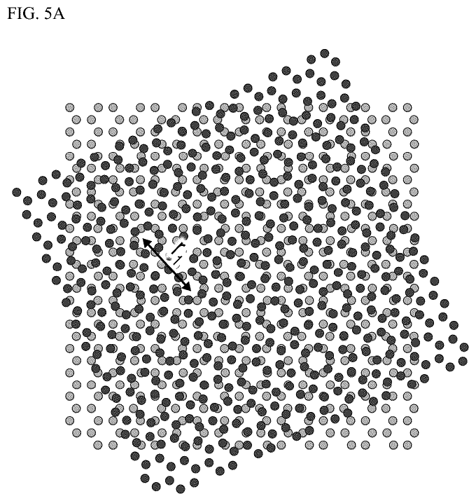

FIG. 1 is a perspective view of an apparatus for adjusting spacing between Moiré superlattices of two-dimensional (2-D) materials according to an embodiment of the present disclosure. FIGS. 2A and 2B are plan views of the apparatus for adjusting spacing between Moiré superlattices of 2-D materials according to an embodiment of the present disclosure. FIG. 3 is a cross-sectional view of a heterostructure 2-D material according to an embodiment of the present disclosure. FIG. 4 is a plan view of the heterostructure 2-D material according to an embodiment of the present disclosure.

Referring to FIGS. 1 to 4, an apparatus 100 for adjusting spacing (or the length/size) between Moiré superlattices of 2-D materials according to an embodiment of the present disclosure includes an electrode 120, a power supply 130, and an electric wire 140, and may further include a switch 210 according to circumstances.

The 2-D material means a material which has a semiconductor characteristic because atoms or compounds are arranged in a layer and which may be manufactured as a high-performance electronic device. The 2-D material may be implemented as a material, such as graphene, transition metal dichalcogenide (TMDC), black phosphorous (BP), or hBN.

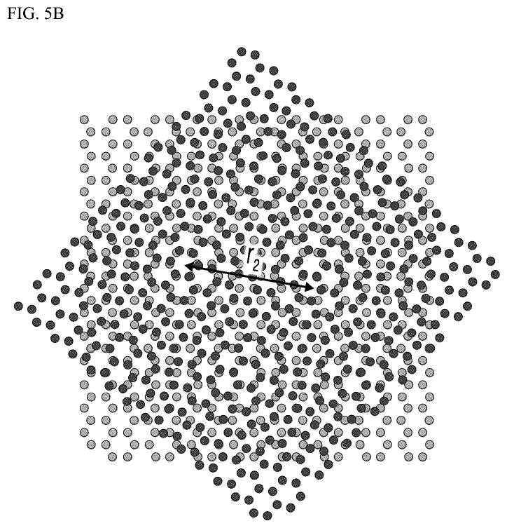

If such a 2-D material is subjected to heterojunction by a van der Waals layered bond, superconducting properties, electrical properties, semiconductor properties, or optical properties of materials that are bonded together are different depending on the type of each material that is bonded, or the angle of each material that is bonded. In particular, if 2-D materials that form a heterostructure 2-D material 110 have an angle therebetween, as illustrated in FIG. 5, Moiré patterns are formed, and superlattices are formed.

FIGS. 5A and 5B are diagrams illustrating Moiré patterns that are formed based on the angles of the heterostructure 2-D material.

FIGS. 5A and 5B exemplify Moiré patterns that are formed when any one of 2-D materials is rotated at a different angle. As illustrated in FIG. 5A, it may be seen that when any one of the 2-D materials is rotated at a relatively smaller angle, spacing of r₁ is formed between superlattices of the 2-D materials within the Moiré pattern. As illustrated in FIG. 5B, it may be seen that when any one of the 2-D materials is rotated at a relatively greater angle, spacing of r₂ that is relatively longer than the spacing r₁ is formed between superlattices of the 2-D materials within the Moiré pattern. As described above, it may be seen that spacing between superlattices of the 2-D materials within the Moiré pattern that is formed depending on a rotation angle of the 2-D material is different. A change in the spacing between the superlattices means a change in the characteristic of the heterostructure 2-D material 110.

Referring back to FIGS. 1 to 4, conventionally, if the heterostructure 2-D material has already been manufactured, it is impossible to adjust an angle between the 2-D materials including the heterostructure 2-D material. However, the apparatus 100 for adjusting spacing between Moiré superlattices of 2-D materials may adjust an angle between 2-D materials even after the manufacturing of the 2-D materials by rotating any one of the 2-D materials including the heterostructure 2-D material. Accordingly, the apparatus 100 for adjusting spacing between Moiré superlattices of 2-D materials may change the characteristics of a heterostructure 2-D material that has been previously manufactured, if necessary.

Referring to FIGS. 3 and 4, the heterostructure 2-D material 110 has a structure in which 2-D materials are subjected to heterojunction by a van der Waals layered bond. The heterostructure 2-D material 110 includes a fixing part 114 and a rotation part 118. The fixing part 114 includes an insulator 310 and a 2-D material 320. The rotation part 118 includes an insulator 330, a 2-D material 340 and an electrode 350.

The insulator 310 is disposed on one surface (i.e., a surface opposite to a surface of the 2-D material 320 which comes into contact with the other 2-D material 340) of the 2-D material 320 within the fixing part 114, and insulates the 2-D material 320. The insulator 310 is disposed on one surface of the 2-D material 320, and electrically and physically separates the 2-D material 320 and an external electrode. If the 2-D material 320 is structurally exposed to an external environment, the characteristics of the 2-D material 320 may be easily changed. In order to prevent such a change, the insulator 310 is disposed on one surface of the 2-D material 320, and electrically and physically separates the 2-D material 320 from an external environment. The insulator 310 may be implemented with hBN, but the present disclosure is not essentially limited. The insulator 310 may be substituted with any material if the material has a characteristic capable of electrical and physical insulation.

The 2-D material 320 has one surface coming into contact with the insulator 310 and the other surface coming into contact with the 2-D material 340. The 2-D material 320 is disposed on the insulator 310, and is subjected to heterojunction with the 2-D material 340 by a van der Waals layered bond. Accordingly, the 2-D materials 320 and 340 may have a very low resistance or frictional force therebetween, so that the 2-D material 340 included in the rotation part 118 may be moved or rotated by an external force.

The rotation part 118 also includes the insulator 330 and the 2-D material 340. The 2-D material 340 has one surface coming into contact with the 2-D material 320, forms a Van der Waals layered bond, and has the other surface coming into contact with the insulator 330.

The insulator 330 has one surface coming into contact with the 2-D material 340 and has the other surface coming into contact with the electrode 350.

The electrode 350 comes into contact with the other surface of the insulator 330, and is rotated by electrostatic attraction applied by the electrode 120. The electrode 350 is rotated by the electrostatic attraction, and is rotated, along with the insulator 330 that comes into contact with the electrode 350 and the 2-D material 340 that comes into contact with the insulator 330. The 2-D material 340 may be easily rotated by an external force because the 2-D material 340 is subjected to heterojunction with the 2-D material 320 by the a van der Waals layered bond and has a very low resistance or frictional force as described above.

The electrode 350 is implemented in the form of sawteeth in which the electrode is rotated around a central axis 358, and includes a through hole 354 therein. The electrode 350 is made of a metal material that is subjected to electrostatic attraction, and is implemented in the form of sawteeth the inside of which is empty. As the through hole 354 is implemented within the electrode 350, light from the outside of the electrode 350 may be incident on the through hole 354 of the electrode 350. The incident light may be discharged to the outside of the electrode 350 via the through hole 354.

The sawteeth of the electrode 350 are implemented as many as a first multiple of a preset numerical value. In this case, the preset numerical value is a natural number (in particular, a natural number equal to or greater than 2). As the numerical value or the first multiple is increased, an implementation of the sawteeth of the electrode 350 becomes complicated, but the rotation angle of the electrode 350 may be adjusted more finely by the electrode 120. In general, the number of sawteeth of the electrode 350 may be implemented to be greater than the number of the electrodes 120 that is described later.

Referring to FIGS. 1 and 2, the electrode 120 is disposed to be spaced apart from the electrode 350 on the outer circumferential surface of the heterostructure 2-D material 110, in particular, the electrode 350 by a predetermined distance. The electrode 120 is also disposed as many as a second multiple of a preset numerical value. The electrodes 120 may be disposed at an equal interval. Likewise, as the numerical value or the second multiple is increased, the number of electrodes 120 that are disposed is increased. Accordingly, the rotation angle of the electrode 350 may be more finely adjusted. The electrode 120 generates electrostatic attraction by receiving a voltage from the power supply 130. As any one or a plurality of electrodes 120 generates the electrostatic attraction, the electrode 350 that is made of metal, in particular, some of the sawteeth of the electrode 350 are subjected to the electrostatic attraction, and moves to a location at which the some sawteeth face a corresponding electrode 120. In this case, the electrode 350 is rotated by the electrostatic attraction because the electrode 350 includes the central axis 358, so that both the insulator 330 and the 2-D material 340 are rotated.

The power supply 130 applies a voltage to each electrode 120 so that any one or a plurality of electrodes 120 generates electrostatic attraction. As illustrated in FIG. 2A, one power supply 130 may apply a voltage to all of the electrodes 120. As illustrated in FIG. 2B, the power supply 130 may be implemented in a plural number, and each of the power supplies 130 may apply a voltage to only a predetermined electrode 120. In this case, if the power supply 130 is implemented in a plural number as illustrated in FIG. 2B, the power supplies 130 may be implemented by a second multiple number. The power supplies 130 may apply voltages to a preset number of (different) electrodes 120 simultaneously.

The electric wire 140 transfers a voltage that is supplied by the power supply 130 to each of the electrodes 120 by electrically connecting the power supply 130 and the electrodes 120.

If one power supply 130 is included in the apparatus 100 for adjusting spacing between Moiré superlattices of 2-D materials as illustrated in FIG. 2A, switches 210a to 210n may be additionally included in the apparatus 100 for adjusting spacing between Moiré superlattices of 2-D materials. Each of the switches 210a to 210n is disposed in an electrical path of the power supply 130 and each of the electrodes 120, and adjusts whether to supply each of the electrodes 120 with a voltage that is supplied by the power supply 130. Only any one or a plurality of specific electrodes 120 may need to generate electrostatic attraction according to circumstances. To this end, the switches 210a to 210n are disposed at the aforementioned locations, and adjust the supply of voltages to the electrodes 120, respectively.

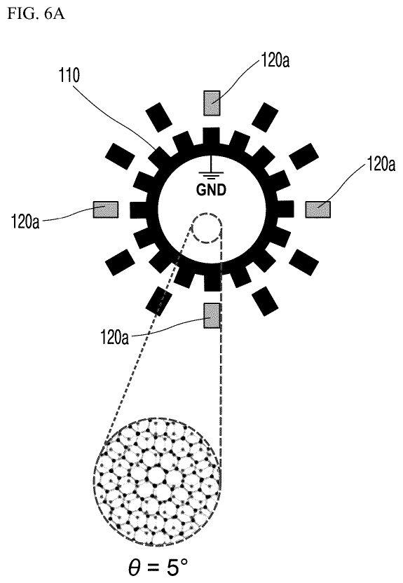

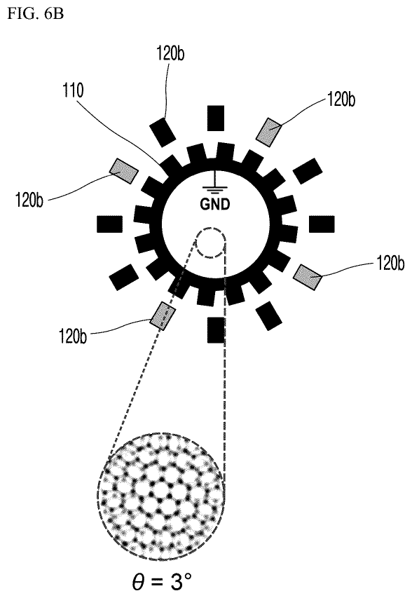

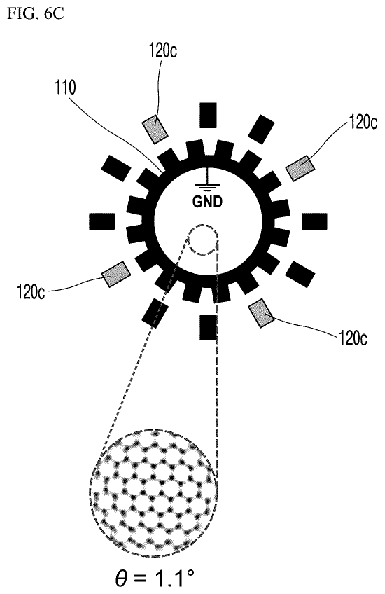

The apparatus 100 for adjusting spacing between Moiré superlattices of 2-D materials, which has such a construction, may operate as illustrated in FIG. 6.

FIGS. 6A-6C are diagrams illustrating an operation of the apparatus for adjusting spacing between Moiré superlattices of 2-D materials according to an embodiment of the present disclosure.

Referring to FIG. 6A, one power supply 130 or any one of a plurality of power supplies 130 may apply a voltage to one electrode (e.g., any one of electrodes 120a) or apply a voltage to a preset number of the electrodes 120a simultaneously. As described above, the sawteeth of the electrode 350 are implemented by the first multiple of the preset numerical value. The electrodes 120 are disposed as many as the second multiple of the preset numerical value. FIG. 6A illustrates a case in which the preset numerical value is 4, the first multiple is 4, and the second multiple is 3. Accordingly, a voltage may be applied to only any one electrode (e.g., any one of the electrodes 120a). As illustrated in FIG. 6A, a voltage may be applied to the preset number of electrodes 120a. In applying the voltage to the preset number of electrodes 120a, the voltage is applied to the electrodes 120a that are disposed to have equal intervals. In applying the voltage to any one electrode (e.g., any one of the electrodes 120a) or the preset number of electrodes 120a, one power supply 130 may apply the voltage to the electrode 120a, or any one of the power supplies that are implemented as many as the second multiple may fixedly apply the voltage to the corresponding electrode 120a or the corresponding electrodes 120a.

When the voltage is applied to only any one electrode (e.g., any one of the electrodes 120a), a sawtooth that belongs to the sawteeth of the electrode 350 and that is most adjacent to the corresponding electrode is rotated at a predetermined angle so that the sawtooth is parallel to the corresponding electrode. The electrode 350 is rotated at the predetermined angle. Accordingly, the 2-D material 340 is also rotated, so that spacing between the Moiré superlattices of the 2-D material may be adjusted.

When the voltage is applied to the preset number of electrodes 120a disposed to have the equal intervals, a sawtooth that belongs to the sawteeth of the electrode 350 and that is most adjacent to each of the electrodes 120a is rotated at a predetermined angle so that the sawtooth is parallel to the corresponding electrode. The preset number of all of the sawteeth of the electrode 350 may be disposed in parallel to the electrodes 120a because the sawteeth of the electrode 350 are also implemented by the first multiple of the preset numerical value. The rotation speed of the electrode 350 or the speed at which spacing between Moiré superlattices of the 2-D material is adjusted may become fast compared to a case in which one electrode 120 is used because the plurality of electrodes 120 generates electrostatic attraction and rotates the sawteeth of the electrode 350.

Referring to FIG. 6B, a voltage may be applied to an electrode (e.g., any one of electrodes 120b) that is adjacent to the electrode 120a to which a voltage has been applied or a preset number of electrodes 120b. In such a case, as in the previous case, a sawtooth of the electrode 350 is rotated at a predetermined angle so that the sawtooth is parallel to the corresponding electrode 120b. The same is true of a case illustrated in FIG. 6C. A voltage may be applied to an electrode (e.g., any one of electrodes 120c) or a preset number of electrodes 120c. Accordingly, the sawtooth of the electrode 350 may be rotated to be parallel to the corresponding electrode 120c.

FIGS. 6A-6C illustrate that a voltage is applied to only any one electrode or a set of preset number of electrodes, but the present disclosure is not limited thereto. A voltage may be applied to any one electrode (e.g., any one of the electrodes 120a) and an additional electrode (e.g., any one of the electrodes 120b or 120c) that is adjacent to the any one electrode 120a simultaneously. A voltage may be applied to the electrode 120a and the electrode 120b or 120c simultaneously. If the voltage is applied as described above, some of the sawteeth of the electrode 350 are subjected to electrostatic attraction from any one electrode, and the remaining some of the sawteeth of the electrode 350 are subjected to electrostatic attraction from another electrode that is adjacent to the any one electrode. Accordingly, when a voltage is applied to different electrodes simultaneously as described above, the sawteeth of the electrode 350 are properly aligned with all of the electrodes, respectively, and may be rotated by a middle degree compared to a case in which a voltage is applied to any one electrode. Assuming that the electrode 350 and the 2-D material 340 are rotated about 5° if a voltage is applied to the electrode 120a as illustrated in FIG. 6A and the electrode 350 and the 2-D material 340 are rotated about 3° if a voltage is applied to the electrode 120b as illustrated in FIG. 6B, when a voltage is applied to the electrode 120a and the electrode 120b simultaneously, the electrode 350 and the 2-D material 340 may be rotated about 4°, that is, a middle degree between 5° and 3°.

As in the aforementioned process, the apparatus 100 for adjusting spacing between Moiré superlattices of 2-D materials can adjust the degree of rotation of the 2-D material 340 and rotate the 2-D material 340 precisely and conveniently, by adjusting whether to apply a voltage to which electrode 120. The apparatus 100 for adjusting spacing between Moiré superlattices of 2-D materials may adjust spacing between Moiré superlattices of the heterostructure 2-D material 110 by a desired length although the heterostructure 2-D material 110 has been previously manufactured.

If spacing between the Moiré superlattices has been adjusted by the apparatus 100 for adjusting spacing between Moiré superlattices of 2-D materials, the following process may be performed in order to verify whether the spacing has been adjusted to desired spacing.

First, spacing between Moiré superlattices of the heterostructure 2-D material 110 or the rotation angle of the 2-D material 340 may be checked based on electrical characteristics. When a voltage is applied to the 2-D materials 320 and 340, the heterostructure 2-D material 110 has a different superlattice density depending on a rotation angle of the 2-D material 340. After the superlattice density of the heterostructure 2-D material 110 is measured, the spacing between the Moiré superlattices of the heterostructure 2-D material 110 or the rotation angle of the 2-D material 340 may be checked based on whether the superlattice density of the heterostructure 2-D material 110 has a desired characteristic.

Alternatively, the spacing between the Moiré superlattices of the heterostructure 2-D material 110 or the rotation angle of the 2-D material 340 may be checked based on optical characteristics. After light is made to be incident on the heterostructure 2-D material 110, a second harmonic generation intensity of the heterostructure 2-D material 110 may be measured based on reflected light that is reflected by the heterostructure 2-D material 110. The second harmonic generation intensity also has a different value depending on a rotation angle of the 2-D material 340. An optical characteristic test can be easily performed on the heterostructure 2-D material 110 because the electrode 350 includes the through hole 354 as described above. After the second harmonic generation intensity of the heterostructure 2-D material 110 is measured, spacing between Moiré superlattices of the heterostructure 2-D material 110 or a rotation angle of the 2-D material 340 may be checked based on whether the second harmonic generation intensity of the heterostructure 2-D material 110 has a desired characteristic.

Accordingly, the apparatus 100 for adjusting spacing between Moiré superlattices of 2-D materials can adjust the rotation angle of the electrode 350 or the 2-D material 340 again based on the results of the check, and can rotate the electrode 350 or the 2-D material 340 at a desired rotation angle by adjusting the rotation angle more precisely. Accordingly, the apparatus 100 for adjusting spacing between Moiré superlattices of 2-D materials can adjust the heterostructure 2-D material 110 so that the heterostructure 2-D material 110 has spacing between Moiré superlattices, although the heterostructure 2-D material 110 has been previously manufactured.

The above description is merely a description of the technical spirit of the present embodiment, and those skilled in the art may change and modify the present embodiment in various ways without departing from the essential characteristic of the present embodiment. Accordingly, the embodiments should not be construed as limiting the technical spirit of the present embodiment, but should be construed as describing the technical spirit of the present embodiment. The technical spirit of the present embodiment is not restricted by the embodiments. The range of protection of the present embodiment should be construed based on the following claims, and all of technical spirits within an equivalent range of the present embodiment should be construed as being included in the scope of rights of the present embodiment.

What is claimed is:

1. A heterostructure two-dimensional (2-D) material, comprising:
a first insulator;
a first 2-D material having one surface coming into contact with the first insulator;
a second 2-D material having one surface coming into contact with the first 2-D material and forming a van der Waals layered bond;
a second insulator having one surface coming into contact with the second 2-D material; and
an electrode configured to come into contact with the other surface of the second insulator and rotated by electrostatic attraction from an outside.

2. The heterostructure 2-D material of claim 1, wherein the first insulator and the first 2-D material are fixed.

3. The heterostructure 2-D material of claim 1, wherein the second insulator, the second 2-D material, and the electrode are rotated.

4. The heterostructure 2-D material of claim 3, wherein the second insulator and the second 2-D material are rotated along with the rotation of the electrode.

5. The heterostructure 2-D material of claim 1, wherein the electrode is implemented in a form of sawteeth that are rotated around a central axis of the electrode.

6. The heterostructure 2-D material of claim 5, wherein the electrode is made of a metal material that is subjected to the electrostatic attraction.

7. An apparatus for adjusting spacing between Moiré superlattices of two-dimensional (2-D) materials, the apparatus comprising:
the heterostructure 2-D material according to claim 1;
a plurality of second electrodes disposed to be spaced apart from the electrode by a predetermined distance on an outer circumferential surface of the electrode and configured to generate the electrostatic attraction by a voltage;
a power supply configured to apply the voltage to each of the plurality of second electrodes so that any one or a plurality of the second electrodes generates the electrostatic attraction;
an electric wire configured to transfer the voltage supplied by the power supply to each of the plurality of second electrodes by electrically connecting the plurality of second electrodes and the power supply; and
a plurality of switches each disposed in an electrical path of the power supply and each of the plurality of second electrodes and configured to adjust whether to supply each of the plurality of second electrodes with the voltage supplied by the power supply.

8. The apparatus of claim 7, wherein sawteeth of the electrode comprise sawteeth that are implemented as many as a first multiple of a preset numerical value.

9. The apparatus of claim 8, wherein the plurality of second electrodes is disposed as many as a second multiple of the preset numerical value.

10. The apparatus of claim 9, wherein the plurality of second electrodes is disposed at equal intervals.

11. An apparatus for adjusting spacing between Moiré superlattices of two-dimensional (2-D) materials, the apparatus comprising:
the heterostructure 2-D material according to claim 1;
a plurality of second electrodes disposed to be spaced apart from the electrode by a predetermined distance on an outer circumferential surface of the electrode and configured to generate the electrostatic attraction by a voltage;
a power supply configured to apply the voltage to each of the plurality of second electrodes so that any one or a plurality of the second electrodes generates the electrostatic attraction and to apply the voltage to a preset number of second electrodes simultaneously; and
an electric wire configured to transfer the voltage supplied by the power supply to each of the plurality of second electrodes by electrically connecting each of the plurality of second electrodes and the power supply.

12. The apparatus of claim 11, wherein the plurality of second electrodes is disposed as many as a second multiple of a preset numerical value.

13. The apparatus of claim 12, wherein the power supply applies the voltage to the plurality of second electrodes disposed to have equal intervals, in applying the voltage to the preset number of second electrodes simultaneously.
